(19) United States
(12) Patent Application Publication
(10) Pub. No.: US 2019/0006196 A1
(43) Pub. Date: Jan. 3, 2019

(54) METHOD FOR PACKAGING CHIP AND CHIP PACKAGE STRUCTURE

(71) Applicants: BOE TECHNOLOGY GROUP CO., LTD., Beijing (CN); Beijing BOE Display Technology Co., Ltd., Beijing (CN)

(72) Inventor: Lianjie QU, Beijing (CN)

(21) Appl. No.: 15/957,955

(22) Filed: Apr. 20, 2018

(30) Foreign Application Priority Data
Jul. 3, 2017 (CN) 201710536546.2

(51) Int. Cl. H01L 21/56; H01L 23/498; H01L 21/48; H01L 23/31; H01L 21/78

(52) U.S. Cl. CPC H01L 21/561; H01L 21/566; H01L 21/568; H01L 23/49816; H01L 24/11; H01L 21/563; H01L 23/3135; H01L 21/78; H01L 21/4825

(57) ABSTRACT

A method for packaging a chip, including: forming a release layer on a first panel-level substrate, and forming redistribution layers respectively on predetermined regions on the release layer, the redistribution layers located in different regions being insulated from each other, and forming a first dielectric layer during the process of forming the redistribution layers; connecting a chip and a pillar connected to the chip to the redistribution layer formed in the predetermined region through a solder cap on the pillar; packaging the chip to form an encapsulation layer; and removing the first panel-level substrate and the release layer, and forming a solder ball on one side of the redistribution layer.

### CROSS REFERENCE TO RELATED APPLICATIONS

This application claims the benefit of China Patent Application No. 201710536546.2, entitled “METHOD FOR PACKAGING CHIP AND CHIP PACKAGE STRUCTURE” filed with the China Patent Office on Jul. 3, 2017, the entire content of which is hereby incorporated by reference.

### TECHNICAL FIELD

The present disclosure relates to the technical field of semiconductor, and in particular, to a method for packaging a chip and a chip package structure.

### BACKGROUND

With the continuous development of integrated circuit technology, electronic products are increasingly becoming more miniature, more intelligent, and more reliable. In contrast, integrated circuit packaging directly affects the performance of integrated circuits, electronic modules, and even the entire machine. With integrated circuit wafers are gradually shrinking, and the level of integration is becoming increasingly high, requirements are becoming ever higher on the integrated circuit packaging.

The chip packaging of the traditional semiconductor industry mainly includes the following processes: cutting the chips on the wafer into separate chips, re-arranging qualified chips on the substrate in a regular manner, and then performing packaging and forming a re-distribution layer (RDL) and a solder ball.

However, due to the small size (typically 6-inch, 8-inch, and 12-inch) of the substrate used in the semiconductor industry, the output scale after packaging is limited.

It should be noted that the information disclosed in the foregoing background section is only for enhancement of understanding of the background of the disclosure and therefore may include information that does not constitute prior art that is already known to those of ordinary skill in the art.

### SUMMARY

Embodiments of the present disclosure employ the following technical solution.

On one hand, there is provided a method for packaging a chip, including: forming a release layer on a first panel-level substrate, and forming redistribution layers respectively on predetermined regions on the release layer, the redistribution layers located in different regions being insulated from each other, and forming a first dielectric layer during the process of forming the redistribution layers; connecting a chip and a pillar connected to the chip to the redistribution layer formed in the predetermined region through a solder cap on the pillar; packaging the chip to form an encapsulation layer; and removing the first panel-level substrate and the release layer, and forming a solder ball on one side of the redistribution layer.

In an exemplary embodiment, before connecting a chip and a pillar connected to the chip to the redistribution layer formed in the predetermined region through a solder cap on the pillar, the method for packaging a chip further includes: fixing a plurality of wafers to a second panel-level substrate, the wafer includes a plurality of chips; forming a pillar and a solder cap on a side of each chip away from the second panel-level substrate; forming a second dielectric layer, the second dielectric layer being filled around the pillar to expose the solder cap; and forming the individual chips and the pillars connected to the chips by dicing.

In an exemplary embodiment, the first dielectric layer is disconnected between any adjacent predetermined regions; after forming the encapsulation layer, and before removing the first panel-level substrate, the method for packaging a chip further includes: making the encapsulation layer between adjacent chips disconnected in the disconnected region of the first dielectric layer, wherein the encapsulation layer encapsulates the first dielectric layer.

In an exemplary embodiment, for any of the chips, the redistribution layer connected thereto extends beyond the edge of the chip.

In an exemplary embodiment, the material of the release layer is a chemical release material or a laser release material.

In an exemplary embodiment, forming the pillar includes: forming the pillar by exposure, development, and electroforming processes in sequence.

In an exemplary embodiment, the first dielectric layer and the second dielectric layer have the same material.

In an exemplary embodiment, the wafer has a shape of a regular polygon; and a plurality of the wafers are seamlessly arranged on the second panel-level substrate.

Based on the above, in an exemplary embodiment, the pillar is a copper pillar, and the first panel-level substrate is a tempered glass substrate.

In another aspect, there is provided a chip package structure which may be manufactured by any of the above method for packaging a chip.

### BRIEF DESCRIPTION OF THE DRAWINGS

In order to more clearly describe the technical solutions in the embodiments of the disclosure or in the prior art, the drawings used in the description of the embodiments or the related art will be briefly described below. Apparently, the drawings in the following description are only some embodiments of the present disclosure, those skilled in the art can also obtain other drawings based on these drawings without any creative effort.

FIG. 1 is a first schematic flowchart of a method for packaging a chip provided by the present disclosure;

FIG. 2 is a schematic diagram of a redistribution layer and a first dielectric layer formed on a first panel-level substrate provided by the present disclosure;

FIG. 3 is a schematic diagram of connecting the chip to the redistribution layer through the solder cap on the pillar on the basis of FIG. 2;

FIG. 4a is a first schematic diagram after being packaged on the basis of FIG. 3;

FIG. 4b is a second schematic diagram after being packaged on the basis of FIG. 3;

FIG. 5a is a schematic diagram of removing the release layer and the first panel-level substrate and forming a solder ball on the basis of FIG. 4a;

FIG. 5b is a schematic diagram of removing the release layer and the first panel-level substrate and forming a solder ball on the basis of FIG. 4b;

FIG. 6 is a schematic diagram of a chip package provided by the present disclosure;

FIG. 7 is a second schematic flowchart of a method for packaging a chip provided by the present disclosure;

FIG. 8a is a first schematic diagram of fixing a plurality of wafers on a second panel-level substrate provided by the present disclosure;

FIG. 8b is a second schematic diagram of fixing a plurality of wafers on a second panel-level substrate provided by the present disclosure;

FIG. 8c is a schematic sectional view taken along line AA′ of FIG. 8a;

FIG. 9 is a schematic diagram of forming a pillar and a solder caps on a chip;

FIG. 10 is a schematic diagram of forming a second dielectric layer on the basis of FIG. 9; and

FIG. 11 is a schematic diagram of forming individual chips and a pillar and a solder cap for connecting the chips on the basis of FIG. 10.

### DETAILED DESCRIPTION

The following clearly describes the technical solutions in the embodiments of the present disclosure with reference to the accompanying drawings in the embodiments of the present disclosure. It is apparent that the described embodiments are merely a part of the embodiments of the present disclosure, but not all of the embodiments. All other embodiments obtained by a person of ordinary skill in the art based on the embodiments of the present disclosure without creative efforts shall fall within the protection scope of the present disclosure.

An embodiment of the present disclosure provides a method for packaging a chip, as shown in FIG. 1, including the following steps.

In S10, as shown in FIG. 2, a release layer 20 is formed on a first panel-level substrate 10, and redistribution layers 30 are respectively formed on predetermined regions on the release layer 20, and the redistribution layers 30 located in different regions are insulated from each other. During the process of forming the redistribution layers 30, a first dielectric layer 40 is also formed.

The first panel-level substrate 10 is a large-sized substrate used in the panel industry, for example, a substrate of 1100 mm×1300 mm, a substrate of 2200 mm×2500 mm, and so on. With respect to a silicon substrate, on one aspect, the present disclosure can reduce the usage of a silicon substrate, and can reduce costs, and on the other hand, the size of the substrate of the present disclosure can be larger.

The release layer 20 can be first peeled off through a corresponding process. In addition, since the redistribution layers 30 and the first dielectric layer 40 are formed on the release layer 20, the release layer 20 should not be affected in the process of forming the redistribution layers 30 and the first dielectric layer 40. In view of this, in an exemplary embodiment, the material of the release layer 20 is a chemical release material or a laser release material.

The chemical release material includes amorphous silicon, resins, and the like. The laser release material includes laser release material such as oxides.

The redistribution layer 30 can realize step-by-step amplification of the chip leads, thereby realizing the nano to micron scale conversion of the chip leads. When the chip leads reach the micron level, they can be accurately interconnected with other devices.

Based on the function of the redistribution layer 30, it can be seen that the redistribution layer 30 located in a predetermined region is for electrically connecting with one chip.

The redistribution layer 30 includes: a plurality of metal distribution layers including metal wires; one first dielectric layer 40 disposed between adjacent metal distribution layers. The metal wires disposed in two adjacent metal distribution layers are electrically connected to each other through via holes on the first dielectric layer 40 between the two metal distribution layers

It should be noted here that the two lines marked with “30” in FIG. 2 represent the metal wires in the two metal distribution layers respectively, and the part marked with “40” substantially includes multiple layers of first dielectric layers 40. The adjacent layers of first dielectric layers 40 are separated by a metal distribution layer. On this basis, the via hole on the first dielectric layer 40 between two layers of metal distribution layers, which is for electrically connecting the metal wires in the two layers of metal distribution layers is not shown in FIG. 2.

It should be understood by those skilled in the art that since the redistribution layer 30 needs to be electrically connected with the chip 50, after the redistribution layer 30 and the first dielectric layer 40 are formed, at the side farthest away from the first panel-level substrate 10, a connecting point (also referred to as a pad) of the redistribution layer 30 for electrically connecting to the chip is exposed from the dielectric layer 40

The redistribution layer 30 and the first dielectric layer 40 can be formed through film deposition, exposure and development, etching, and other processes. However, the redistribution layer 30 can also be formed by electroforming or the like.

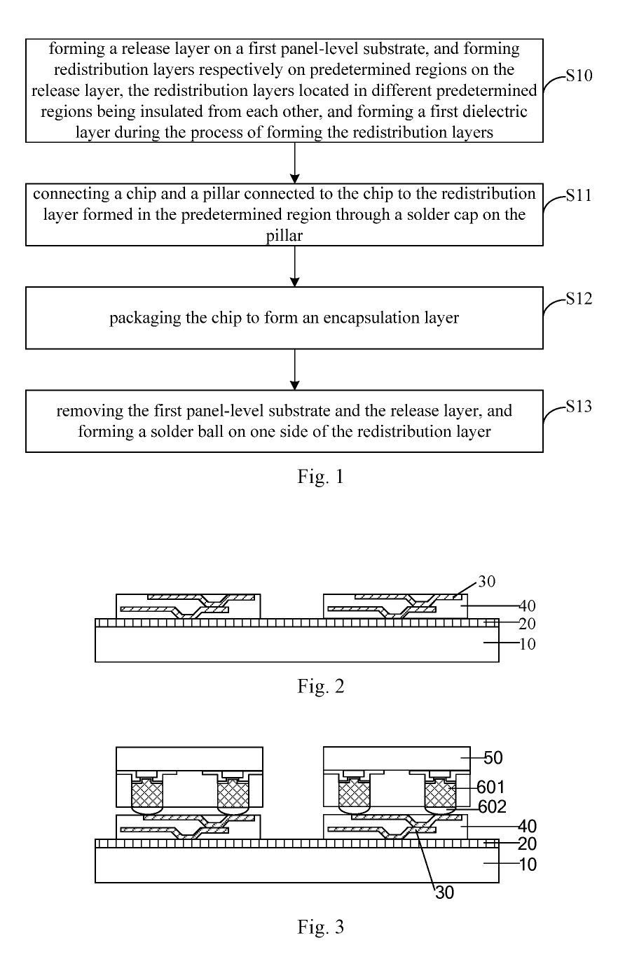

In step S11, as shown in FIG. 3, the chip 50 and the pillar 601 connected to the chip 50 are connected to the redistribution layer 30 formed in the predetermined region through the solder cap 602 on the pillar 601.

The redistribution layer 30 in each predetermined region is electrically connected to one chip 50. The chip 50 is a qualified chip 50 passed through testing.

The chip 50 may include a semiconductor device or integrated circuit that has been fabricated on a semiconductor substrate. For example, chip 50 may include a substrate including silicon or other semiconductor material, an insulating layer on the substrate, conductive elements (including, for example, metal pads, plugs, via holes, or wires), and contact pads over the conductive elements.

The pillar 601 is electrically connected to the contact pad of the chip 50. After the redistribution layer 30 is connected to the solder cap 602, the redistribution layer 30 is electrically connected to the chip 50 through the solder cap 602 and the pillar 601.

Since copper material has excellent thermal and electrical conductivity, preferably the pillar 601 is a copper pillar.

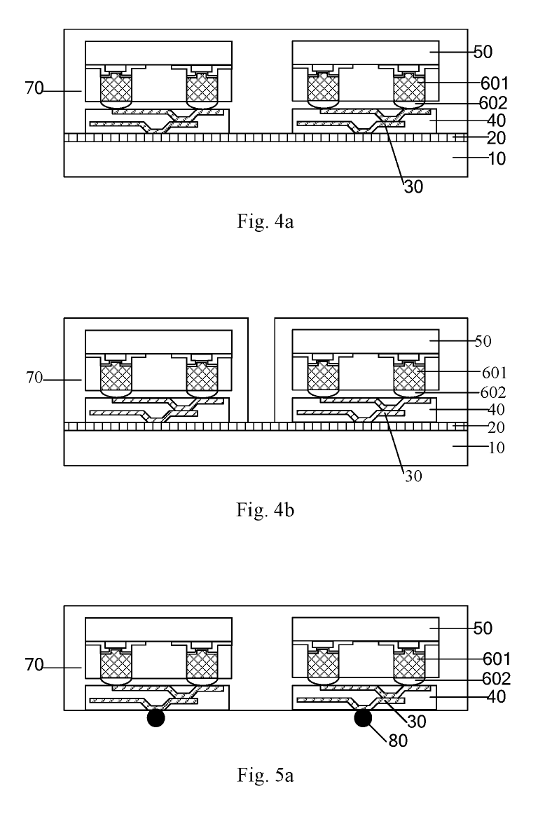

In step S12, as shown in FIGS. 4a and 4b, the chip 50 is packaged to form an encapsulation layer 70.

The encapsulation layer 70 is located around each chip 50 for protecting each chip 50.

Since the sealing property of an epoxy molding compound (EMC) is excellent and the plastic molding is easy, the material of the encapsulation layer. 70 is preferably EMC.

EMC is a thermosetting plastic formed by taking epoxy resin as matrix resin, phenolic resin as curing agent, together with some fillers, such as fillers, flame retardants, colorants, coupling agents and other trace components, through reaction between the epoxy ring opening of the epoxy resin and the phenolic resin to produce a cross-linking curing effect under the action of heat and curing agent.

Here, as shown in FIG. 4b, in an exemplary embodiment, the first dielectric layer 40 is disconnected between any adjacent predetermined regions. Based on this, after the encapsulation layer 70 is formed, before removing the first panel-level substrate 10, the method for packaging a chip further includes: making the encapsulation layer 70 between adjacent chips 50 disconnected in the disconnected region of the first dielectric layer 40. The encapsulation layer 70 encapsulates the first dielectric layer 40.

The encapsulation layer 70 between the adjacent chips 50 is disconnected in the disconnected region of the first dielectric layer 40, for example, by a cutting process.

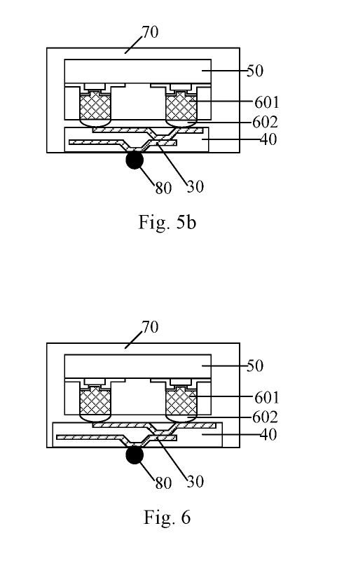

In this way, after the subsequent removal of the first panel-level substrate 10 and the release layer 20, one packaged chip 50 can be directly obtained (as shown in FIG. 5b).

It should be noted that in order to effectively protect the chip 50, a spacing between adjacent chips 50 should be reserved. Therefore, when setting the predetermined region, the spacing between the chips 50 during packaging should be fully considered.

In step S13, as shown in FIGS. 5a and 5b, the first panel-level substrate 10 and the release layer 20 are removed, and a solder ball 80 is formed on one side of the redistribution layer 30.

Here, with respect to the case of FIG. 5b, the solder balls 80 may be formed by individually performing spot welding on each chip 50 by a pick-up machine.

When the material of the release layer 20 is a chemical release material, the release layer 20 may be chemically peeled off from the packaged chip 50, and the corresponding first panel-level substrate 10 is also peeled off. When the material of the release layer 20 is a laser release material, the release layer 20 may be peeled off from the packaged chip 50 by laser irradiation, and the corresponding first panel-level substrate 10 is also peeled off.

Solder balls 80 are metal materials including tin, lead, copper, silver, gold, tantalum, and other metals or alloys thereof. Methods of forming solder balls 80 include printing, ball implantation, laser sintering, electroplating, electroless plating, sputtering, and the like.

An embodiment of the present disclosure provides a method for packaging a chip. By employing a panel-level substrate as the first panel-level substrate 10, a large-area exposure can be performed on a production line of panel industry, thereby forming the redistribution layer 30 in the predetermined regions by etching. It can ensure the accuracy of the metal wires in the redistribution layer 30. On this basis, for each predetermined region, a qualified chip 50 is electrically connected to the redistribution layer 30 formed in the predetermined region, and the chip 50 is packaged to realize a large-scale package, which can improve package efficiency and output efficiency, and reduce the cost of the packaging in the traditional semiconductor industry. In addition, since the process of forming the redistribution layer 30 and the process of forming the chip 50 having the pillar 601 and the solder cap 602 are performed separately, it can reduce the complexity of the processes for the redistribution layer 30 and the chip 50 having the pillar 601 and the solder cap 602. The accuracy won't be lowered too much due to the large number of layers, and it can ensure high resolution. Therefore, the present disclosure can also realize the packaging of the high-end chip 50.

As shown in FIG. 6, in an exemplary embodiment, for any chip 50, the redistribution layer 30 connected thereto exceeds the edge of the chip 50.

Here, in forming the redistribution layer 30 and the first dielectric layer 40, the overall size of the redistribution layer 30 and the first dielectric layer 40 may be made larger than the size of the single chip 50. In this way, after the chip 50 is electrically connected to the redistribution layer 30 through the solder cap 602 on the pillar 601, the redistribution layer 30 can be extended beyond the edge of the chip 50.

The redistribution layer 30 extends beyond the edge of the chip 50 to form a fan-out package, which can achieve better connectivity and design flexibility.

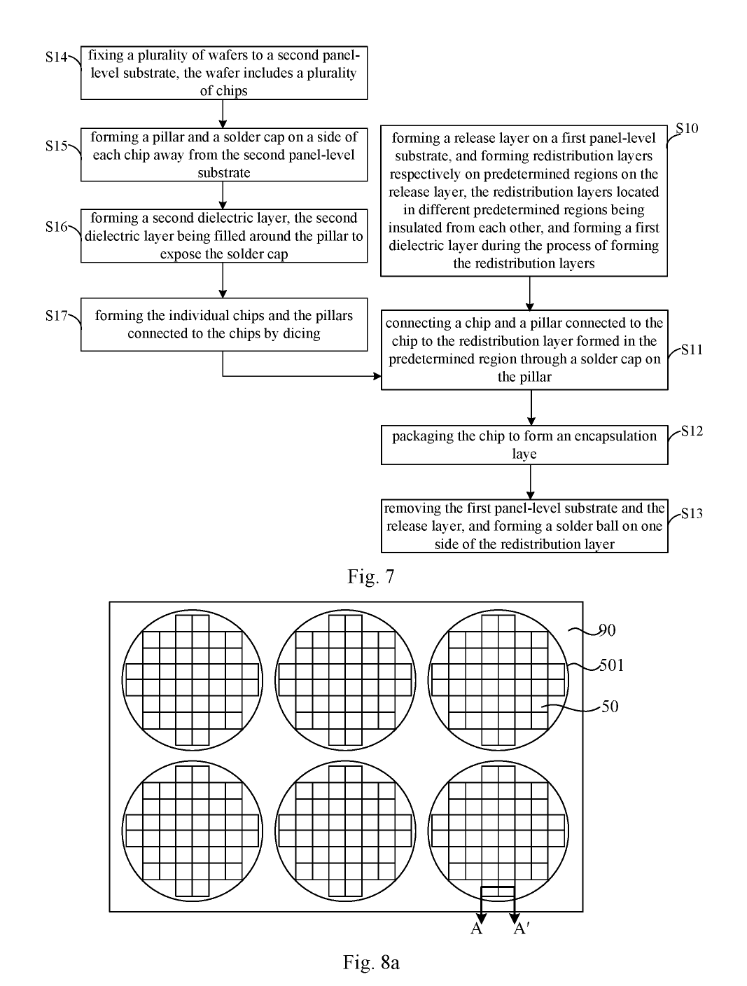

In an exemplary embodiment, before the above step S11, as shown in FIG. 7, the packaging method further includes the followings steps.

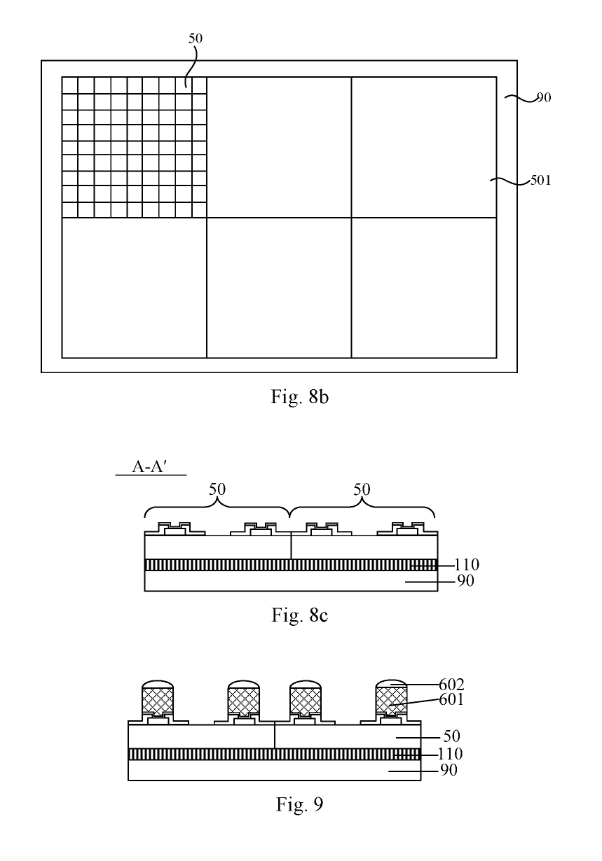

In step S14, as shown in FIGS. 8a, 8b and 8c, a plurality of wafers 501 are fixed on the second panel-level substrate 90. The wafer 501 includes a plurality of chips 50.

Like the first panel-level substrate 10, the second panel-level substrate 90 is also a large substrate employed by the panel industry. It is preferable that the first panel-level substrate 10 and the second panel-level substrate 90 have the same size.

The wafer 501 may be fixed to the second panel-level substrate 90 through an adhesive layer 110. The wafer 501 may be, for example, a silicon wafer.

Here, in order to dispose as much wafers 501 as possible on the second panel-level substrate 90, the shape of the wafer 501 may be made into a regular polygon so that the plurality of wafers 501 may be seamlessly arranged on the second panel-level substrate 90. In this way, the utilization of the second panel-level substrate 90 can be increased, thereby further increasing the output efficiency.

In step S15, as shown in FIG. 9, a pillar 601 and a solder cap 602 are formed on the side of each chip 50 away from the second panel-level substrate 90.

Here, the pillar 601 may be formed by exposure, development, and electroforming processes in sequence.

That is, after the photoresist is applied, the area of the pillar 601 is exposed after being exposed and developed, and then the pillar 601 is formed by an electroforming process. It can allow the pillar 601 to be formed with higher accuracy.

The solder cap 602 may be formed by a reflow manner.

It should be noted that the present disclosure is not limited to forming the pillar 601 through the above processes, but through other processes also.

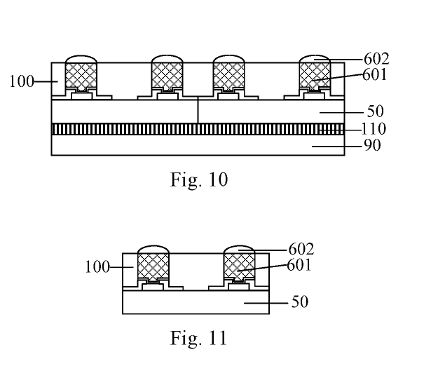

In step S16, as shown in FIG. 10, a second dielectric layer 100 is formed, and the second dielectric layer 100 is filled around the pillar 601 to expose the solder cap 602.

In an exemplary embodiment, the materials of the first dielectric layer 40 and the second dielectric layer 100 are the same, which can simplify the process and reduce the cost. The materials of the first dielectric layer 40 and the second dielectric layer 100 may be, for example, a polymer such as polyimide (PI).

In step S17, as shown in FIG. 11, the individual chips 50 and the pillars 601 connected to the chips 50 are formed by dicing.

When each wafer 501 includes N chips 50 and M wafers 501 are disposed on the second panel-level substrate 90, after dicing, M×N individual chips 50 are obtained, where M, N is a positive integer. However, the pillars 601 located on different chips 50 are also separated from each other by dicing.

To avoid damaging the second panel-level substrate 90 during dicing to reuse the second panel-level substrate 90, the second panel-level substrate 90 may be removed before dicing in this step.

An appropriate method may be selected according to the material of the adhesive layer 110 to separate the adhesive layer 110 from the chip 50 to remove the second panel-level substrate 90.

The material of the adhesive layer 110 may be, for example, a double-sided tape. In this case, the double-sided tape may be reduced in viscosity by heating to achieve separation from the chip 50 to remove the second panel-level substrate 90. Alternatively, the material of the adhesive layer 110 may be, for example, a UV adhesive glue. In this case, the UV adhesive glue may be reduced in viscosity by UV light to achieve separation from the chip 50 to remove the second panel-level substrate 90.

In the embodiment of the present disclosure, by first fixing a plurality of wafers 501 to the first panel-level substrate 10, the pillars 601 and the solder caps 602 and the second dielectric layer 100 can be formed over a large area of the production line in the panel industry, and thus can be cut through. After that, more chips 50 can be obtained, further improving the output.

Based on the above, since the stress of the encapsulation layer 70 is very large, and the bending resistance, impact resistance and resistance of the multilayer process of the tempered glass are strong, it is preferable to use a tempered glass substrate as the first panel-level substrate 10. Therefore, it can avoid the problem that the first panel-level substrate 10 may be bent or even broken due to inability to withstand a large stress.

The embodiment of the present disclosure also provides a chip package structure (as shown in FIG. 5b and FIG. 6), which can be prepared by any of the above method for packaging a chip.

The foregoing descriptions are merely specific implementation manners of the present disclosure, but the protection scope of the present disclosure is not limited thereto. Modification or replacement within the technical scope disclosed by the present disclosure readily devised by those skilled in the art should be within the scope of the disclosure. Therefore, the protection scope of the present disclosure should be based on the protection scope of the claims.

What is claimed is:

1. A method for packaging a chip, comprising:
forming a release layer on a first panel-level substrate, and forming redistribution layers respectively on predetermined regions on the release layer, the redistribution layers located in different predetermined regions being insulated from each other, and forming a first dielectric layer during the process of forming the redistribution layers;
connecting a chip and a pillar connected to the chip to the redistribution layer formed in the predetermined region through a solder cap on the pillar;
packaging the chip to form an encapsulation layer; and
removing the first panel-level substrate and the release layer, and forming a solder ball on one side of the redistribution layer.

2. The method for packaging a chip according to claim 1, wherein before connecting a chip and a pillar connected to the chip to the redistribution layer formed in the predetermined region through a solder cap on the pillar, the method for packaging the chip further comprises:
fixing a plurality of wafers to a second panel-level substrate, the wafer comprises a plurality of chips;
forming a pillar and a solder cap on a side of each chip away from the second panel-level substrate;
forming a second dielectric layer, the second dielectric layer being filled around the pillar to expose the solder cap; and
forming the individual chips and the pillars connected to the chips by dicing.

3. The method for packaging a chip according to claim 1, wherein the first dielectric layer is disconnected between any adjacent predetermined regions;
after forming the encapsulation layer, and before removing the first panel-level substrate, the method for packaging the chip further comprises:
making the encapsulation layer between adjacent chips disconnected in the disconnected region of the first dielectric layer, wherein the encapsulation layer encapsulates the first dielectric layer.

4. The method for packaging a chip according to claim 1, wherein for any of the chips, the redistribution layer connected to the chip extends beyond the edge of the chip.

5. The method for packaging a chip according to claim 1, wherein the material of the release layer is a chemical release material or a laser release material.

6. The method for packaging a chip according to claim 2, wherein the step of forming the pillar comprises:
forming the pillar by processes of exposure, development, and electroforming in sequence.

7. The method for packaging a chip according to claim 2, wherein the first dielectric layer and the second dielectric layer have the same material.

8. The method for packaging a chip according to claim 2, wherein the wafer comprises a shape of a regular polygon; and
a plurality of the wafers are seamlessly arranged on the second panel-level substrate.

9. The method for packaging a chip according to claim 1, wherein the pillar is a copper pillar.

10. The method for packaging a chip according to claim 2, wherein the pillar is a copper pillar.

11. The method for packaging a chip according to claim 3, wherein the pillar is a copper pillar.

12. The method for packaging a chip according to claim 4, wherein the pillar is a copper pillar.

13. The method for packaging a chip according to claim 1, wherein the first panel-level substrate is a tempered glass substrate.

14. The method for packaging a chip according to claim 2, wherein the first panel level substrate is a tempered glass substrate.

15. The method for packaging a chip according to claim 3, wherein the first panel level substrate is a tempered glass substrate.

16. The method for packaging a chip according to claim 4, wherein the first panel level substrate is a tempered glass substrate.

17. A chip package structure manufactured by the method for packaging a chip according to claim 1.

18. The chip package structure according to claim 17, wherein the chip and the pillar connected to the chip are connected by a solder cap on the pillar before being connected to the redistribution layer formed in the predetermined area, the method for packaging a chip further comprises:
fixing a plurality of wafers to a second panel-level substrate, the wafer comprises a plurality of chips;
forming a pillar and a solder cap on a side of each chip away from the second panel-level substrate;
forming a second dielectric layer, the second dielectric layer being filled around the pillar to expose the solder cap; and
forming the individual chips and the pillars connected to the chips by dicing.

19. The chip package structure according to claim 18, wherein the first dielectric layer and the second dielectric layer have the same material.

20. The chip packaging structure according to claim 18, wherein the wafer comprises a shape of a regular polygon; and
a plurality of the wafers are seamlessly arranged on the second panel-level substrate.
